(19) United States
(12) Patent Application Publication
(10) Pub. No.: US 2016/0300985 A1
(43) Pub. Date: Oct. 13, 2016

(54) Optoelectronic Device and Method for Producing an Optoelectronic Device

(71) Applicant: OSRAM Opto Semiconductors GmbH, Regensburg (DE)

(72) Inventors: Britta Göötz, Regensburg (DE); Tilman Schlenker, Nittendorf (DE); Jürgen Moosburger, Lappersdorf (DE)

(21) Appl. No.: 15/100,532

(22) PCT Filed: Dec. 17, 2014
(86) PCT No.: PCT/EP2014/078263

§ 371 Date: May 31, 2016

(30) Foreign Application Priority Data
Dec. 18, 2013 (DE) 10 2013 114 337.7
Feb. 13, 2014 (DE) 10 2014 101 804.4

(51) Int. Cl. H01L 33/50; H01L 33/56

(52) U.S. Cl. CPC H01L 33/504; H01L 33/56; H01L 2933/005; H01L 2933/0041

(57) ABSTRACT

An optoelectronic device and a method for producing an optoelectronic device are disclosed. The optoelectronic device includes an optoelectronic semiconductor chip and a conversion element arranged on the optoelectronic semiconductor chip. The conversion element includes a matrix material which includes a glass frit, a first phosphor, embedded in the glass frit, and cavities and a second phosphor arranged in the cavities of the matrix material.

This patent application is a national phase filing under section 371 of PCT/EP2014/078263, filed Dec. 17, 2014, which claims the priority of German patent application 10 2013 114 33737, filed Dec. 18, 2013, and German patent application 10 2014 101 804.4, filed Feb. 13, 2014, each of which is incorporated herein by reference in its entirety.

### TECHNICAL FIELD

The invention relates to an optoelectronic device and a method for producing an optoelectronic device.

### BACKGROUND

The wavelength of the emitted light of an optoelectronic device containing an optoelectronic semiconductor chip, e.g. a light-emitting diode (LED chip), is determined by the material properties of the semiconductor material, substantially by the band gap thereof. Therefore, LEDs only emit light in a narrow spectral range. In order to produce LEDs of different colors, on the one hand various semiconductor materials can be used or, as an alternative thereto, so-called conversion elements can be used.

In order to produce conventional conversion elements, polymer materials, e.g. silicone, in which a phosphor is embedded, are used. A disadvantage of these conversion elements is the considerable scattering of the light emitted by the semiconductor chip at the phosphor particles embedded in the polymer matrix, which results in the device having a reduced luminosity. Furthermore, heat is produced during the wavelength conversion and during the operation of the LED chip. If the heat is not sufficiently dissipated, this results in a reduction in the luminous intensity and the service life of the LED. A conventional polymer matrix only has a low thermal conductivity (<1 W/mK).

Furthermore, ceramic conversion materials are known in which the ceramic material consists of a phosphor and is applied onto the light exit side of an LED chip. For this, a plurality of ceramic layers can also be used, wherein each individual layer can comprise a particular phosphor. The problem thereby exists that a chemical reaction between the individual phosphors can occur during the sintering of the ceramic materials. As a result, the conversion efficiency is reduced. Furthermore, the emitted radiation of this conversion element has a high angle dependency.

### SUMMARY OF THE INVENTION

Embodiments of the invention provide an optoelectronic device which comprises an optoelectronic semiconductor chip and a conversion element arranged on the optoelectronic semiconductor chip. In various embodiments the conversion element comprises a matrix material which includes a glass frit and a first phosphor, embedded in the glass frit, and cavities. A second phosphor is arranged in the cavities of the matrix material.

In further embodiments the matrix material which includes the glass frit, in which the first phosphor is embedded, and the cavities can also be referred to as a porous glass frit, i.e. a glass frit containing pores or cavities. The matrix material can consist of the glass frit, in which the first phosphor is embedded, or can comprise other components in addition to the glass frit. The cavities can be connected together at least partially and/or extend to the surface of the conversion element. The term “cavities” is to be understood here and hereinafter to also include capillaries, ducts and pores of different shapes.

The glass frit can contain, or consist of, SiO₂, B₂O₃, P₂O₅, GeO₂, As₂O₃, As₂O₅, MgO, Al₂O₃, TiO₂, PbO and/or ZnO as the main component. Preferably, the glass frit is a glass frit with a low melting point. In order to lower the melting temperature, the glass frit can contain, in addition to the main component, alkali and/or alkaline earth metal oxides such as Na₂O, K₂O, CaO, SrO and BaO. The glass frit can consist of the main component and an alkali and/or alkaline earth metal oxide. For example, the glass frit consists of SiO₂ and Na₂O.

Hereinafter, conversion elements are referred to as being components which can at least partially absorb a so-called primary radiation emitted, for example, by the optoelectronic semiconductor chip, and then can emit a so-called secondary radiation. For this purpose, the conversion elements contain phosphors which include luminescent materials. If only a part of the primary radiation is absorbed by the phosphors, this process is referred to as partial conversion. The wavelength of the primary and secondary radiation can vary within the UV to IR range, wherein the wavelength of the secondary radiation is greater than the wavelength of the primary radiation.

The optoelectronic semiconductor chip can be designed, for example, as a light-emitting diode having a semiconductor layer sequence which is based on an arsenide, phosphide and/or nitride compound semiconductor material system and has an active, light-producing region. Such semiconductor chips are known to the person skilled in the art and will not be described in more detail herein.

The optoelectronic device having the semiconductor chip and the conversion element can furthermore be arranged, for example, on a carrier and/or in a housing or casting compound and be electrically contactable by means of electric connections, e.g. via a so-called lead frame.

According to one embodiment of the invention, the optoelectronic semiconductor chip emits a primary radiation, wherein the conversion element is arranged in the beam path of the primary radiation. The first phosphor converts the primary radiation at least partially into a first secondary radiation and the second phosphor converts the primary radiation at least partially into a second secondary radiation. The wavelengths of the two secondary radiations differ from one another. The overall emission of the optoelectronic device is thus a superimposition of the primary radiation, the first secondary radiation and the second secondary radiation or—in the case of complete conversion—of the first and second secondary radiation, which in each case can give an external observer an impression of warm-white light.

In one embodiment, the first phosphor includes garnets doped with rare earth metals. In a preferred embodiment, the first phosphor can include yttrium aluminum oxide (YAG), lutetium aluminum oxide (LuAG) and/or terbium aluminum oxide (TAG). Furthermore, the first phosphor can be doped with an activator which is selected from a group including cerium, europium, neodymium, terbium, erbium, praseodymium, samarium and manganese. Examples of this are cerium-doped yttrium aluminum garnets and cerium-doped lutetium aluminum garnets.

The second phosphor can be selected from a group including silicate compounds, sulfide compounds, nitrides, garnets, organic compounds, quantum dots and combinations thereof. The invention is thus not limited to the use of an inorganic compound as the second phosphor. In a preferred embodiment, laser dyes, e.g. perylenes, are used as organic compounds and CdSe and/or InP are used as quantum dots.

According to one embodiment, the second phosphor can be embedded in a polymer. The polymer can be a transparent adhesive. The term “transparent” is to be understood here and hereinafter to mean in this context that the adhesive is substantially or completely transmissive to the radiation emitted by the optoelectronic device. For example, low-viscosity silicones can be used as the polymer or transparent adhesive. Therefore, the cavities of the matrix material can be completely filled with the polymer and are thus free of air. Owing to the improved thermal conductivity of the polymer, compared with air, the heat dissipation during the electrical operation is thereby ensured and the service life of the optoelectronic device is thus increased. That is to say, at least some, more particularly all, of the cavities can be completely filled, within the scope of production tolerances, with the mixture of the second phosphor and polymer or transparent adhesive. In particular, it is possible that the conversion element is adhered to the outer surface of a semiconductor chip by means of the polymer or transparent adhesive. At this point, the polymer or transparent adhesive can also then be filled with particles of the second phosphor.

The conversion element which is arranged in the beam path of the primary radiation, and thus on a light exit side of the semiconductor chip, has, according to one embodiment, spatial dimensions which correspond to the dimensions of the light exit side of the optoelectronic semiconductor chip. The thickness of the conversion element is, in a preferred embodiment, in a range between 50 and 200 μm, particularly preferably between 80 and 150 μm. Therefore, on the one hand a certain stability of the apparatus is ensured during the production process and on the other hand a certain thickness is not exceeded in order to be able to process the apparatus, e.g. in thin film electronics.

The conversion element can be attached to the semiconductor chip by means of a transparent adhesive. The conversion element can thereby be attached to the semiconductor chip by means of an adhesive layer which contains or consists of the transparent adhesive.

In one embodiment, the transparent adhesive is a silicone. The transparent adhesive can be structurally similar to the transparent adhesive in which the second phosphor is embedded, but can have a different viscosity.

In one embodiment, the adhesive layer includes a transparent adhesive which is selected to be identical to the transparent adhesive in which the second phosphor is embedded and arranged in the cavities of the matrix material. In this embodiment, the adhesive layer can be produced by the adhesive which contains the second phosphor and which is arranged in the cavities of the matrix material and, via pores which extend to the surface of the matrix material, likewise extends to the surface of the matrix material. In this embodiment, the adhesive layer can contain the second phosphor. It is possible that the adhesive layer consists of the transparent adhesive and the second phosphor.

According to one embodiment, the primary radiation is selected from the ultraviolet to blue spectral range, the first secondary radiation is selected from the yellow-green spectral range and the second secondary radiation is selected from the red spectral range. The first and second phosphors can convert the ultraviolet to blue primary radiation completely or partially into the respective secondary radiation. The superimposition of all three radiations, or, in the case of complete conversion, the two secondary radiations, gives an impression of warm-white light. The spectrum of the emitted light can be varied by the concentration of the first and second phosphors. In addition, the color of the radiation emitted by the optoelectronic device can be controlled in that a layer of a polymer is additionally applied onto the conversion element, the second phosphor being embedded in this polymer layer. The thickness of such an additional layer, and the concentration of the second phosphor within this layer, can be selected, depending upon the desired color tone of the radiation emitted by the device and depending upon the second phosphor, from the range of 1 nm to 50 μm and 0.1 to 70 weight percent based on the polymer. If the second phosphor is a nitride or a garnet, the thickness can be selected from a range of 1 to 10 μm and the concentration can be selected from a range of 1 to 10 weight percent. If the second phosphor is a quantum dot or an organic compound, the thickness can be selected from a range of 1 to 10 nm and the concentration can be selected from a range of 0.01 to 0.5 weight percent, e.g. 0.05 weight percent.

The homogeneous distribution of the second phosphor within the cavities of the matrix material ensures a homogeneous color mixture of the primary radiation emitted by the optoelectronic semiconductor chip and the first secondary radiation emitted by the first phosphor and the second secondary radiation emitted by the second phosphor or, in the case of complete conversion, the first secondary radiation emitted by the first phosphor and the second secondary radiation emitted by the second phosphor.

With a refractive index of the glass frit of the matrix material (n_{d}=1.7), compared with a ceramic (n_{d}=2.2), an improved outcoupling of the light to air from the conversion element is ensured.

The matrix material has a higher overall thermal conductivity than, for example, a pure silicone matrix, whereby an efficient heat dissipation is ensured during the operation of the optoelectronic device. As a result, thermal quenching can be reduced for example.

The concentration of the first phosphor and of the second phosphor can be selected, depending upon the desired color tone of the radiation emitted by the device and depending upon the selection of the first and second phosphor, from the range of 0.1 to 70 weight percent based on the matrix material. If the second phosphor is a quantum dot or an organic compound, the concentration can be selected from a range of 0.01 to 0.5 weight percent. If the second phosphor is a nitride or a garnet, the concentration can be selected from a range of 1 to 10 weight percent. The concentration of the first phosphor can be selected from a range of 1 to 10 weight percent.

A method for producing an optoelectronic device is also provided. The method comprises the following method steps: A) providing a semiconductor chip, e.g. an LED chip, B) producing a conversion element, and C) arranging the conversion element on the semiconductor chip. Method step B) thereby includes the method steps of B1) producing a matrix material comprising a glass frit, a first phosphor embedded in the glass frit, and cavities, and B2) arranging a second phosphor in the cavities of the matrix material. This method can be used to produce an optoelectronic device according to the above embodiments. The above statements in relation to the optoelectronic device apply similarly to the device produced by means of the method.

For the production of the matrix material, according to one embodiment, in method step B1) molten glass is mixed with the first phosphor, powdered and sintered. Sintering can take place at a temperature of between 200 and 1000° C., e.g. at 400° C. As an alternative thereto, in method step B1) powdered glass and the first phosphor present in powder form can be mixed together and sintered. In this embodiment, the sintering process takes place below the melting point of the glass.

The design of the structure of the matrix material, in particular the size of the cavities, can be influenced by the temperature and particle size of the used or produced glass powder in method step B1). It is thus possible to adapt the size of the cavities to the size of the second phosphor. When using inorganic compounds as the second phosphor, the size of the cavities can be in the μm range whereas when using organic molecules and quantum dots the size of the cavities can be in the nm range.

In method step B2), the second phosphor can be mixed with a solvent and introduced into the cavities. Then, the solvent can evaporate and/or be evaporated. Evaporation can take place at temperatures between 20° C. and 100° C. depending upon the solvent. Introducing the second phosphor into the cavities can take place at least partially utilizing capillary forces. The solvent can thereby be selected from a group including toluene, acetone, pentane, Chbenzene, isopropanol, heptane and xylene.

In a further embodiment, an electric field is applied during method step B2). As a result, the arrangement of the second phosphor in the cavities of the matrix material can be strengthened, so long as the second phosphor has a charge. For this purpose, the matrix material can be arranged in a container filled with a solvent. In one embodiment, isopropanol is used as the solvent. The matrix material is thereby in contact with a metallic, electrically conductive carrier. By applying a voltage, the diffusion of the charged phosphor particles into the cavities of the matrix material is intensified.

In a method step B3) taking place after method step B2), the cavities of the matrix material are filled with a polymer. The polymer has a higher thermal conductivity than air which ensures a more efficient heat dissipation during the electrical operation.

In an alternative embodiment of the method step B2), the second phosphor embedded in a polymer is introduced into the cavities of the matrix material. This can be effected, for example, partially utilizing capillary forces. The advantage of this embodiment is that it is not necessary to use a solvent in order to introduce the second phosphor into the cavities of the matrix material and thus the method step of evaporating the solvent is omitted. If a transparent adhesive containing the second phosphor is introduced into the cavities, the matrix material can also be attached to the optoelectronic semiconductor chip at the same time with this adhesive.

Owing to the combination of a matrix material including a glass frit, a first phosphor embedded in the glass frit, and cavities, and the arrangement of a second phosphor in the cavities of the matrix material, a chemical reaction between the two phosphors during method step B) is at least substantially avoided because the second phosphor is introduced into the cavities of the matrix material only after method step B1) is complete, in a further method step B2). For example, a possible degradation of the second phosphor owing to high temperatures applied during the sintering in method step B1) is avoided. Furthermore, the second phosphor is otherwise also not subjected to any high temperatures. e.g. by the contact with liquid glass.

Therefore, a material which is unstable at high temperatures and is thus not suitable for a sintering process, as can be performed for example in method step B1), can also be selected as the second phosphor. The first phosphor, in contrast, can comprise a material which, similar to the used glass, can comprise an oxide compound and have a high level of stability at high temperatures. As a result, the degradation of the two phosphors can be at least substantially avoided which ensures a high level of efficiency of the optoelectronic device.

The finished conversion element is arranged on the optoelectronic semiconductor chip. The conversion element can thereby be adhered to the semiconductor chip by means of a transparent adhesive in method step C). According to one embodiment, a transparent adhesive layer is arranged on the semiconductor chip in method step C), the conversion element being able to be arranged on the adhesive layer.

According to a further embodiment, the conversion element can be adhered to the semiconductor chip by means of the transparent adhesive which is filled into the cavities in method step B₃) and in which the second phosphor is embedded and which extends to the surface of the matrix material via the pores of the matrix material.

In an alternative embodiment of method steps B2) and C), in which these methods steps are performed simultaneously, a transparent adhesive containing the second phosphor can be applied to the optoelectronic semiconductor chip before it is introduced into the cavities of the matrix material. Then, the matrix material is positioned over the semiconductor chip, wherein the second phosphor is introduced with the adhesive into the cavities of the matrix material by pressing the matrix material onto the semiconductor chip. The conversion element is thereby simultaneously connected to the optoelectronic semiconductor chip.

### BRIEF DESCRIPTION OF THE DRAWINGS

Further advantages, advantageous embodiments and developments are apparent from the exemplified embodiments described below in conjunction with the figures.

FIG. 1 shows the schematic side view of an optoelectronic device,

FIG. 2 shows the schematic side view of method steps for producing a matrix material of the conversion element of the optoelectronic device according to one embodiment,

FIG. 3 shows the schematic side view of method steps for producing an optoelectronic device according to one embodiment,

FIG. 4 shows the schematic side view of an optoelectronic device according to one embodiment,

FIG. 5 shows the schematic side view of method steps for producing a conversion element according to one embodiment,

FIG. 6 shows the schematic side view of an optoelectronic device according to one embodiment.

### DETAILED DESCRIPTION OF ILLUSTRATIVE EMBODIMENTS

In the exemplified embodiments and figures, like or similar elements or elements acting in an identical manner may each be provided with the same reference numerals. The illustrated elements and their size ratios with respect to each other are not to be considered as being to scale; rather individual elements, such as e.g. layers, components, devices and regions, can be illustrated excessively large for improved clarity and/or for improved understanding.

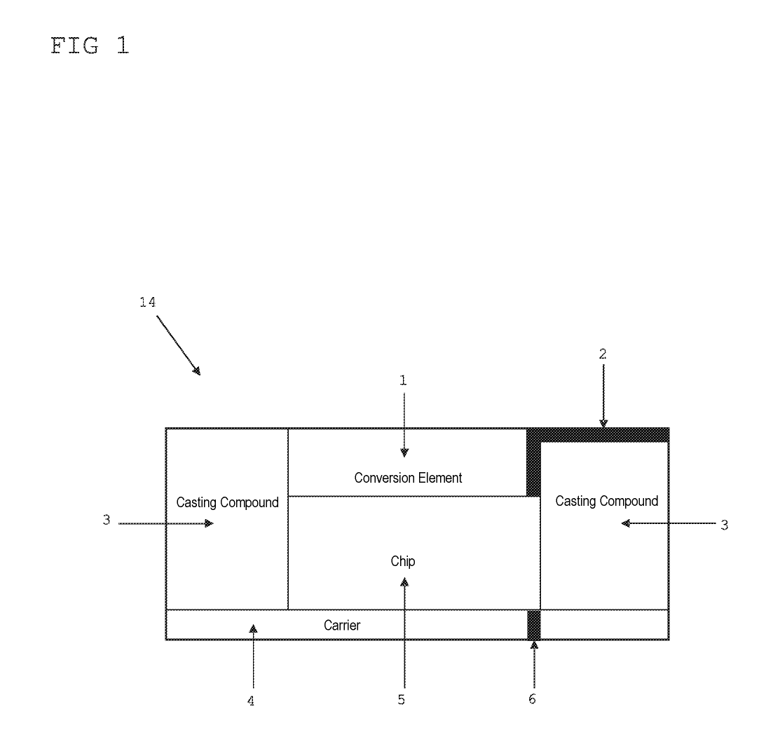

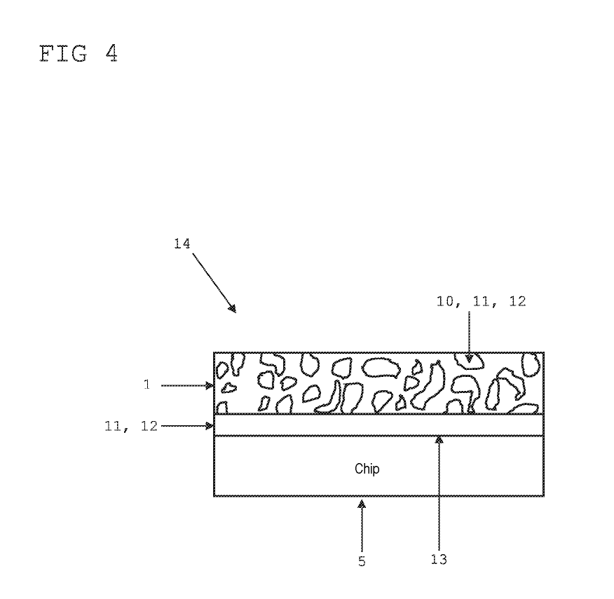

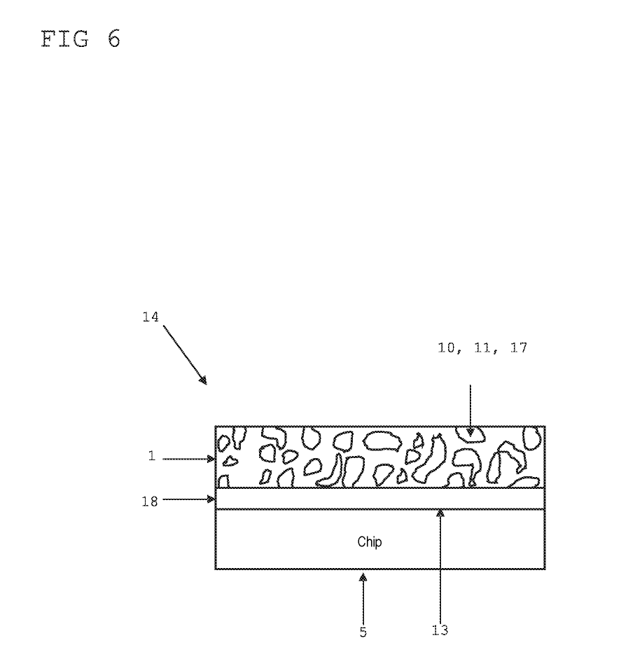

FIG. 1 shows the schematic side view of an optoelectronic device 14, wherein the optoelectronic semiconductor chip 5 is arranged on a carrier 4 and a conversion element 1 is arranged on the semiconductor chip 5. The optoelectronic semiconductor chip 5 is contacted, in this example, by the first contacting portion 2 and the second contacting portion 6. The optoelectronic semiconductor chip 5 and the conversion element 1 are embedded in a casting compound 3 which can be formed, for example, from TiO₂. In the following FIGS. 4 and 6, which each illustrate embodiments of optoelectronic devices 14, the carrier 4, casting compound 3 and contacting portions 2, 6 are not illustrated for the sake of simplicity.

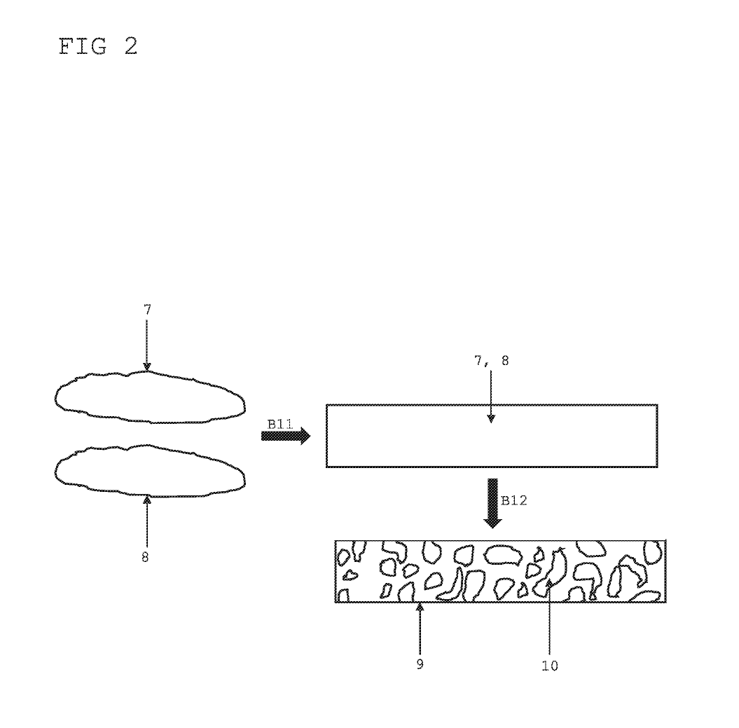

A possible production method for a matrix material is illustrated in FIG. 2. A powdered glass 7 and the first phosphor 8 in powder form are mixed together in a step B11. The mixture of the powdered first phosphor 8 and glass powder 7 is sintered in a further step B12. A matrix material 9 which comprises a glass frit 7, in which a first phosphor 8 is embedded, and cavities 10 of a specific size is thereby produced. The size of the cavities 10 can thereby be influenced by the temperature during the sintering process and the used particle size of the powdered glass 7 and the first phosphor 8 in powder form.

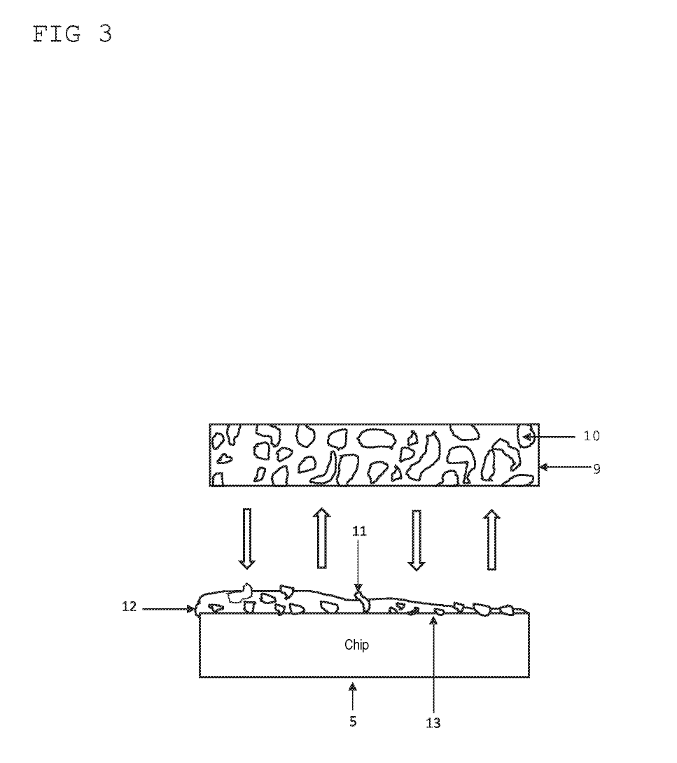

FIG. 3 shows a schematic side view of method steps for producing an optoelectronic device according to one embodiment. The second phosphor 11 is thereby introduced together with a polymer, e.g. a transparent adhesive 12, such as a silicone, into the cavities lo of the matrix material 9. The transparent adhesive 12 containing the second phosphor 11 is arranged on the light exit side 13 of the optoelectronic semiconductor chip 5. Then, by applying pressure, the matrix material 9 can be connected to the optoelectronic semiconductor chip 5, indicated by the arrows shown in FIG. 3. The matrix material 9 comprises cavities 10 which protrude inter alia at the outer surface thereof, and so the transparent adhesive 12 containing the second phosphor 11 can penetrate into these cavities 10. This process can be facilitated by capillary forces which occur. Furthermore, for complete filling of the cavities 10 with the transparent adhesive 12 containing the second phosphor 11, an additional application of pressure can also take place, the pressure being so high that the cavities 10 are completely filled with adhesive 12 and the second phosphor. The conversion element 1 is simultaneously produced in this method step, i.e. the second phosphor 11 is introduced into the cavities lo of the matrix material 9, and the conversion element 1 is attached to the optoelectronic semiconductor chip 5.

FIG. 4 shows the schematic side view of an optoelectronic device 14 according to one embodiment. The device is produced using the methods described in relation to FIGS. 2 and 3, and therefore the second phosphor 11, which, again, is embedded in the transparent adhesive 12, is arranged in the cavities 10 of the matrix material 9. Produced between the optoelectronic semiconductor chip 5 and the conversion element 1 is therefore a thin adhesive layer of the transparent adhesive 12 containing the second phosphor 11, said layer establishing the connection between the conversion element 1 and the optoelectronic semiconductor chip 5.

During operation of the optoelectronic device 14, the optoelectronic semiconductor chip 5 generates a blue to ultraviolet primary radiation when supplied with electrical energy. This radiation exits through the light exit side 13. The primary radiation then passes through the thin adhesive layer of the transparent adhesive 12 containing the second phosphor 11 and through the matrix material 9, in the cavities 10 of which the second phosphor 11 is arranged. The first phosphor 8 contained in the matrix material 9 converts the primary radiation at least partially into a first secondary radiation in the yellow-green spectral range. In addition, the second phosphor 11 at least partially converts the primary radiation into a second secondary radiation in the red spectral range. A warm-white overall radiation is generated by the superimposition of all three radiations, and is emitted by the optoelectronic device 14.

The spectrum of the emitted light of the optoelectronic device 14 can, in addition to the conversion element 1, a further layer containing the second phosphor 11 and the transparent adhesive 12 which is arranged on the conversion element 1 in order to fine-tune the color impression of the radiation emitted by the optoelectronic component 14 depending upon the application (not shown herein).

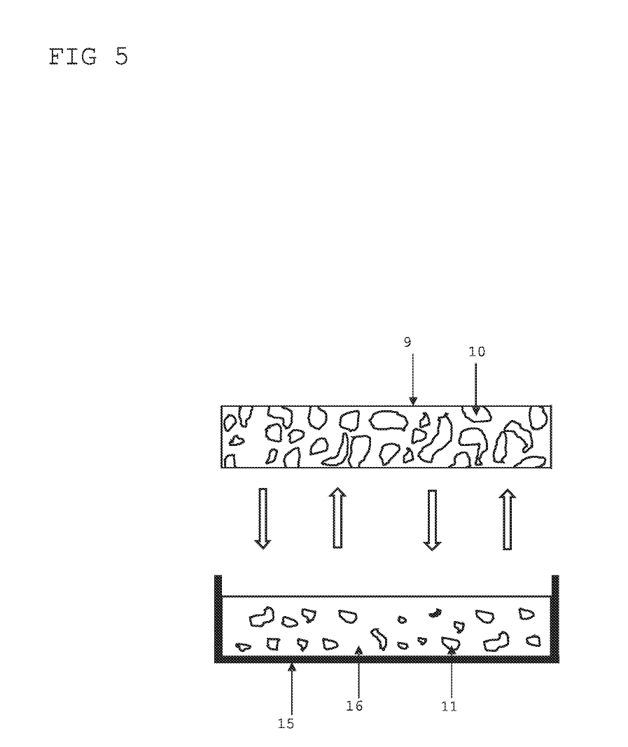

FIG. 5 shows the schematic side view of a method step for producing a conversion element according to a further embodiment. The introduction of the second phosphor 11 into the cavities 10 of the matrix material 9 and the arranging of the conversion element 1 on the light exit side 13 of the optoelectronic semiconductor chip 5 are thereby effected separately from one another (the arrangement is not shown in FIG. 5). The second phosphor 11 is provided in a container 15 which contains a solution and/or suspension 16 of the second phosphor 11 in toluene, acetone, pentane, Cl-benzene, isopropanol, heptane, xylene or a combination of these solvents. The matrix material 9 is at least partially immersed in the solution and/or suspension 16. The solution and/or suspension 16 can thereby diffuse via the cavities 10 on the surface of the matrix material 9 into the cavities 10 thereof, which is at least partially intensified by capillary forces which occur. After a period of time, the matrix material 9 is removed from the container 15 and the solvent and/or suspension 16 in the cavities can evaporate and/or be evaporated. The second phosphor ii thereby remains within the cavities 10 of the matrix material 9.

In order to efficiently embed the second phosphor ii within the cavities 10 of the matrix material 9, this process can also be facilitated—so long as the second phosphor ii has an electrical charge—by applying an electric field.

In order to avoid air as a poor heat conductor, the cavities 10 are then filled up with a polymer, e.g. an adhesive 12 (not shown herein). Filling up occurs by filling, immersion or molding.

FIG. 6 shows the schematic side view of an optoelectronic device 14 according to one embodiment. In this case, the conversion element 1 is connected to the optoelectronic semiconductor chip 5 via an adhesive layer 18, which contains a transparent adhesive, on the light exit side 13 of the optoelectronic semiconductor chip. The adhesive layer 18 with a thickness between 1 and 50 μm contains, for example, the transparent adhesive 12, e.g. silicone. In this embodiment, the cavities 10 of the conversion element 1 are filled with a polymer 17 in which the second phosphor 11 is embedded.

Should it be necessary to regulate the color of the radiation emitted by the optoelectronic device, a layer of the polymer 17 containing the second phosphor 11 can additionally be applied onto the conversion element 1 (not shown herein). In one embodiment, a concentration of the second phosphor 11, which is too low, is introduced into the cavities of the glass frit from the outset. By applying a second layer of the polymer 17 containing the second phosphor 11, e.g. a transparent adhesive 12 onto the conversion element 1, the spectrum of the emitted light of the optoelectronic device 14 can be adapted.

The description made with reference to the exemplified embodiments does not restrict the invention to these embodiments. Rather, the invention encompasses any new feature and any combination of features, including in particular any combination of features in the claims, even if this feature or this combination is not itself explicitly indicated in the claims or exemplified embodiments.

1-16. (canceled)

17. An optoelectronic device comprising:
an optoelectronic semiconductor chip; and
a conversion element arranged on the optoelectronic semiconductor chip, the conversion element comprising:
a matrix material which includes a glass frit, a first phosphor, embedded in the glass frit, and cavities; and
a second phosphor arranged in the cavities of the matrix material.

18. The optoelectronic device according to claim 17, wherein the second phosphor is embedded in a polymer and/or a transparent adhesive, and wherein at least some of the cavities are completely filled with the second phosphor and the polymer and/or the transparent adhesive.

19. The optoelectronic device according to claim 17, wherein the optoelectronic semiconductor chip is configured to emit a primary radiation, wherein the conversion element is arranged in a beam path of the semiconductor chip, wherein the first phosphor at least partially converts the primary radiation into a first secondary radiation, and wherein the second phosphor at least partially converts the primary radiation into a second secondary radiation.

20. The optoelectronic device according to claim 19, wherein the primary radiation is selected from an ultraviolet to blue spectral range, the first secondary radiation is selected from a yellow to green spectral range and the second secondary radiation is selected from a red spectral range.

21. The optoelectronic device according to claim 17, wherein the first phosphor includes garnets doped with rare earth metals.

22. The optoelectronic device according to claim 17, wherein the second phosphor is selected from a group consisting of: silicate compounds, sulfide compounds, nitrides, garnets, organic compounds, quantum dots and combinations thereof.

23. The optoelectronic device according to claim 17, wherein the second phosphor is embedded in a polymer.

24. The optoelectronic device according to claim 17, wherein the conversion element is attached to the optoelectronic semiconductor chip by a transparent adhesive.

25. A method for producing an optoelectronic device, the method comprising:
providing a semiconductor chip;
producing a conversion element; and
arranging the conversion element on the semiconductor chip,
wherein producing the conversion element comprises:
producing a matrix material comprising a glass frit, a first phosphor, embedded in the glass frit, and cavities; and
arranging a second phosphor in the cavities of the glass frit.

26. The method according to claim 25, wherein producing the matrix element comprises mixing molten glass with the first phosphor, powdering the mixed material and sintering the powdered mixed material.

27. The method according to claim 25, wherein producing the matrix material comprises mixing and sintering powdered glass and powdered first phosphor.

28. The method according to claim 25, wherein arranging the second phosphor in the cavities comprises mixing the second phosphor with a solvent and introducing the mixed material into the cavities and thereafter evaporating the solvent.

29. The method according to claim 28, wherein arranging the second phosphor in the cavities comprises applying an electric field.

30. The method according to claim 25, further comprising, after arranging the second phosphor in the cavities, filling the cavities with a polymer.

31. The method according to claim 25, wherein arranging the second phosphor in the cavities comprises embedding the second phosphor in a polymer and/or transparent adhesive and introducing the embedded material into the cavities of the matrix material.

32. The method according to claim 25, wherein arranging the conversion element on the semiconductor chip comprises adhering the conversion element to the semiconductor chip by a transparent adhesive.

33. An optoelectronic device comprising:
an optoelectronic semiconductor chip; and
a conversion element arranged on the optoelectronic semiconductor chip, the conversion element comprising:
a matrix material which includes a glass frit, a first phosphor, embedded in the glass frit and cavities; and
a second phosphor arranged in the cavities of the matrix material, wherein the second phosphor is embedded in a polymer and/or a transparent adhesive.
